(19) United States
(12) Patent Application Publication
(10) Pub. No.: US 2025/0203804 A1
(43) Pub. Date: Jun. 19, 2025

(54) COMPUTER SERVER RACK WITH SLIDE ADAPTER CLIP

(71) Applicant: General Devices Co., INC., Indianapolis, IN (US)

(72) Inventors: Elizabeth Kokinos, Fishers, IN (US); Phillip Saucerman, Indianapolis, IN (US)

(21) Appl. No.: 18/981,394

(22) Filed: Dec. 13, 2024

Related U.S. Application Data
(60) Provisional application No. 63/610,820, filed on Dec. 15, 2023.

(51) Int. Cl. H05K 7/14; H05K 7/18

(52) U.S. Cl. CPC H05K 7/1487; H05K 7/183

(57) ABSTRACT

The present disclosure provides adapter clips for server and rack mounting applications. The purpose of these adapter clips is to convert square-hole racks to be able to accept slides and having round mount holes.

### CROSS REFERENCE TO RELATED APPLICATIONS

This application claims priority to and the benefit of U.S. Provisional Patent Application No. 63/610,820, filed 15 Dec. 2023, the disclosure of which is now expressly incorporated herein by reference.

### BACKGROUND

Computer servers are often mounted on racks to support the computer servers above the ground and to facilitate wiring into larger overall systems. In many instances, server slides are used to couple the computer servers to the racks so that the computer servers can move from retracted to extended positions relative to the rack. In this way, the computer servers can accessed by a user for repair, update, and/or replacement.

Many racks include upright posts for supporting server slides and associated computer servers. The upright posts are formed to include square mount holes for use in coupling the server slides to the rack. However, many server slides are made with attachment flanges having round bolt holes that are not easily coupled to a rack via square mount holes.

To address this incompatibility between square mount holes in a rack and round bolt holes in a server slide, technicians have generally turned to adding cage nuts to the racks. Cage nuts include a threaded nut captured in a housing with bent fingers for coupling the housing to a rack through its square mount holes. Among other things, cage nuts can be tedious to install and remove. Accordingly, there is a need for alternative means for addressing incompatibility between square mount holes in a rack and round bolt holes in a server slide.

### SUMMARY

According to the present disclosure, adapter clips provide a solution for server and rack mounting applications. The purpose of these adapter clips is to convert square-hole racks to be able to accept slides and having round mount holes.

In illustrative embodiments, the adapter clips that provide means for fixing attachment flanges of server slides in position relative to a rack with square mount holes using bolts. The adapter clips each include an exterior panel, an interior panel spaced from the exterior panel, and a spine panel that extends from the exterior panel to the interior panel. Aligned bolt apertures extend through the exterior and interior panels to accept threaded bolt shafts while blocking movement of bolt heads therethrough.

In illustrative embodiments, the exterior panel of the adapter clip includes a primary portion that is parallel to an outer face of the upright post included in the rack and at least one indented temporary-retention portion that is pressed out of alignment from the primary portion. The indented temporary-retention portion is sized to extend into a square mount hole of the upright post of the rack to hold the adapter clip in place relative to the rack during installation of the bolts that couple the server slides to the rack.

In illustrative embodiments, the interior panel of the adapter clip includes a primary portion that is parallel to an inner face of an upright post of the rack and a temporary-retention portion that is pressed out of alignment from the primary portion. The indented temporary-retention portion is sized to extend into a square mount hole of the upright post of the rack to hold the adapter clip in place relative to the rack during installation of the bolts that couple the server slides to the rack.

Also disclosed is a computer server mount assembly. The assembly includes a rack with square mount holes, a server slide with round holes formed in attachment flanges, and adapter clips in accordance with the present disclosure.

Additional features of the present disclosure will become apparent to those skilled in the art upon consideration of illustrative embodiments exemplifying the best mode of carrying out the disclosure as presently perceived.

### BRIEF DESCRIPTIONS OF THE DRAWINGS

The detailed description particularly refers to the accompanying figures in which:

FIG. 1 is a perspective view of a portion of a computer server mount assembly including a rack with square mount holes formed in an upright post, server slides with round holes formed in attachment flanges, and slide adapter clips that provide means for fixing the attachment flanges of the server slides in position relative to the upright post of the rack using bolts as suggested in FIGS. 2 and 3;

FIG. 2 is a detail view of a portion of FIG. 1 showing that the adapter clip includes an exterior panel arranged along an outer face of the upright post included in the server rack, an interior panel arranged along an inner face of the upright post included in the server rack, and a spine panel that interconnects the exterior and interior panels, and further showing that the exterior panel has a primary portion and indented temporary-retention portions that are pressed out of alignment from the primary portion so as to engage the upright post around corresponding square holes and hold the adapter clip in place relative to the rack during installation of bolts that couple the server slides to the rack;

FIG. 3 is an exploded perspective view of the assembly in FIG. 2 showing bolt apertures in the exterior and interior panels of the adapter clip, round holes in the attachment flange of the server slide, and a nut plate with threaded holes for retaining the bolts when passed through the adapter clip and into the attachment flange;

FIG. 4 is a front perspective view of the adapter clip of FIGS. 1-3 showing details of the exterior panel included in the adapter clip;

FIG. 5 is a rear perspective view of the adapter clip of FIGS. 1-3 showing details of the interior panel included in the adapter clip;

FIG. 6 is a side perspective view of the adapter clip of FIGS. 1-3 showing a temporary-retention portion of the interior panel included in the adapter clip pushed out of alignment with the rest of the interior panel to provide for retention of the adapter clip in place relative to the upright post prior to bolts being inserted through the clip;

FIG. 7 is a front elevation view of the adapter clip of FIGS. 1-3;

FIG. 8 is a rear elevation view of the adapter clip of FIGS. 1-3;

FIG. 9 is a first side elevation view of the adapter clip of FIGS. 1-3;

FIG. 10 is a second side elevation view of the adapter clip of FIGS. 1-3;

FIG. 11 is a top plan view of the adapter clip of FIGS. 1-3;

FIG. 12 is a bottom view of the adapter clip of FIGS. 1-3;

FIG. 13 is a front perspective view of a second embodiment of an adapter clip configured for use in the computer server mount assembly of FIGS. 1-3 showing an alternative shapes for bolt apertures formed in the adapter clip;

FIG. 14 is a rear perspective view of the adapter clip shown in FIG. 13;

FIG. 15 is a front perspective view of a third embodiment of an adapter clip configured for use in the computer server mount assembly of FIGS. 1-3 showing an alternative shapes for bolt apertures formed in the adapter clip;

FIG. 16 is a rear perspective view of the adapter clip shown in FIG. 15; and

FIG. 17 is an exploded perspective assembly view of a prior art mounting system including a cage nut configured for use with a rack having square mount holes.

### DETAILED DESCRIPTION

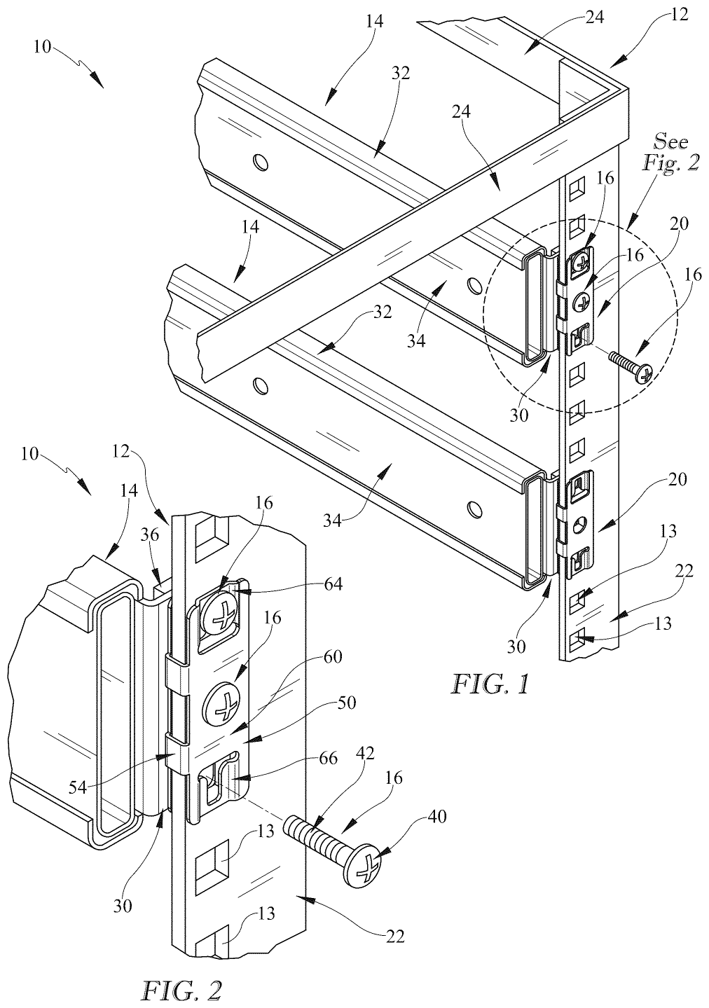

A computer server mount assembly 10 including adapter clips 20 is shown in FIGS. 1-3. The assembly 10 illustratively includes a rack 12, a server slide 14, and bolts 16. The rack 12 is formed to have square mount holes 13 to support coupling of server slides 14 to the rack 12. The server slide 14 is formed to have round bolt holes 15 sized to receive bolts 16 to couple the server slide 14 to the rack 12. The adapter clips 20 provide means for adapting the square mount holes 13 of the rack 12 for coupling with the round bolt holes 15 of the server slide 14 using the bolts 16.

The adapter clip 20 has bolt apertures 61, 62, 63, 71, 72, 73 formed therethrough that locate bolts 16 and block movement of bolt heads 40 through the square mount holes 13 of the rack 12 as shown in FIG. 2. The adapter clip 20 also has temporary-retention features 64, 66, 75 that hold the adapter clip 20 in place relative to the rack 12 prior to installation of the bolts 16 as suggested in FIG. 1. Further, the adapter clip 20 is illustratively made from a sheet of metallic material having a substantially uniform thickness that is cut, bent, and/or pressed into shape, thereby managing manufacturing costs. Additional description of these features of the adapter clip 20 is provided below.

The rack 12 is conventionally used for supporting a number of computer servers (not shown) above an underlying floor as suggested in FIG. 1. The rack 12 typically includes four upright posts 22 and cross bars 24 interconnecting the upright posts 22. The upright posts 22 extend upwardly from the floor and are formed to include a series of square mount holes 13. The cross bars 24 extend horizontally and generally parallel to the underlying floor from one upright post 22 to another to reinforce the overall structure of the rack 12.

The server slide 14 is a telescoping mechanism adapted to support a computer server for sliding movement relative to the rack 12. The server slide 14 illustratively includes an attachment flange 30, a stationary slide member 32, and a movable slide member 34 as shown in FIGS. 1-3. The attachment flange 30 has round holes formed therethrough to receive bolts 16 used to fix the server slide 14 to the rack 12. The stationary slide member 32 is fixed to the attachment flange 30 and may be integrally formed with the attachment flange 30 as shown in the illustrated embodiment. The movable slide member 34 moves along an axis relative to the stationary slide member 32 from a retracted position to an extended position. The movable slide member 34 illustratively includes holes suitable for bolts that couple a computer server (not shown) to the movable slide member 34 for movement therewith. In some embodiments, the server slide 14 may include various locking/releasing mechanisms for holding the movable slide member 34 in preselected positions relative to the stationary slide member 32.

In the illustrative embodiment, a threaded nut plate 36 is fixed to the attachment flange 30 and having threaded holes for retaining the bolts 16 when passed through the adapter clip 20 and the attachment flange 30. The bolts 16 are each made up of a bolt head 40 and threaded shaft 42 that extends from the bolt head 40. Threads of the threaded shaft 42 mate with threads of the threaded holes in the nut plate 36. In other embodiments, the holes in the attachment flange 30 may be threaded or threads of the bolts 16 may engage the attachment flange 30 around the holes. In some embodiments, individual nuts many be used with each bolt 16 to retain the bolts 16.

The adapter clip 20 provides means for fixing the server slides 14 in position relative to the square mount holes 13 of the upright post 22 included in the rack 12 as suggested in FIGS. 1 and 2. To support this fixation, the adapter clip 20 cooperates with the heads 40 of the bolts 16 since the heads 40 are sized such that they would move through the square mount holes 13 of the upright post 22 without an additional structure.

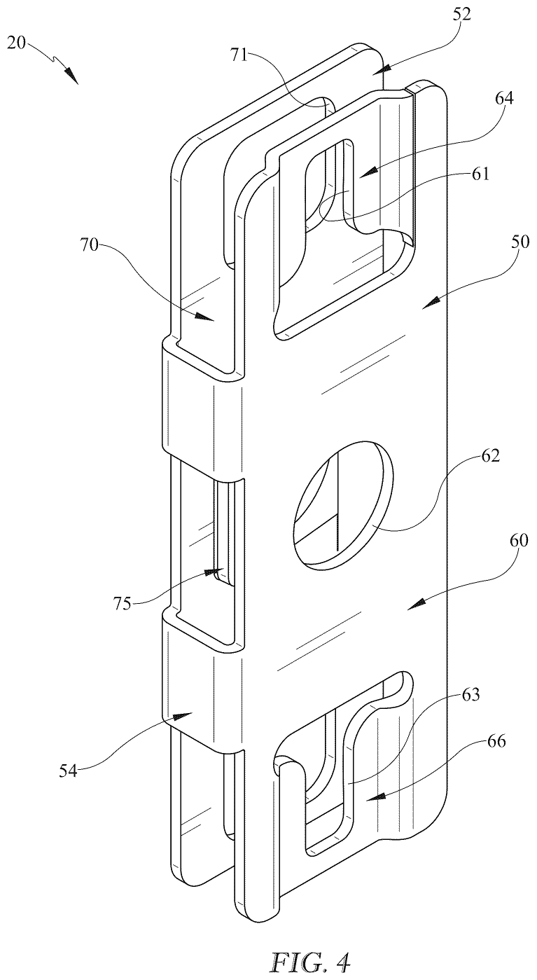

The adapter clip 20 is illustratively a monolithic, metallic stamped part bent into shape as suggested in FIG. 4. Of course, in other embodiments, the adapter clip 20 may be made of polymeric or other suitable materials. The adapter clip 20 includes an exterior panel 50, an interior panel 52, and a spine panel 54. The exterior panel 50 extends along an outer face of the upright post 22 included in the rack 12. The interior panel 52 extends along an interior face of the upright post 22. The spine panel 54 is illustratively made up of two sections that each extend from the exterior panel 50 to the interior panel 52 along a side face of the upright post 22.

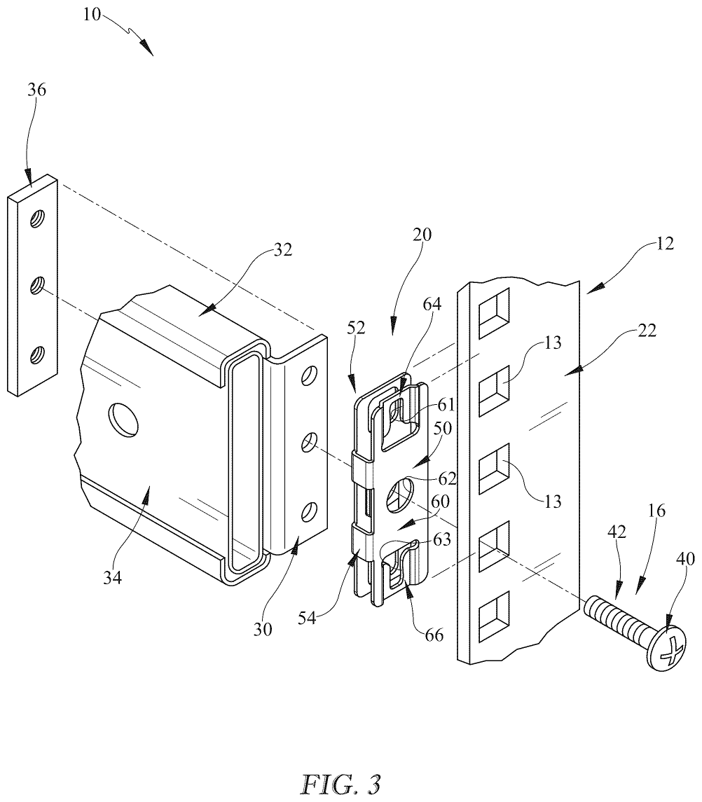

The exterior panel 50 of the adapter clip 20 includes a primary portion 60 that is in a plane parallel to a plane of the outer face of the upright post 22 as shown in FIGS. 2 and 3. The exterior panel 50 is formed to include upper, mid, and lower bolt head apertures 61, 62, 63 sized to receive the threaded shaft 42 of a bolt 16. Each bolt head aperture 61, 62, 63 formed in the exterior panel 50 is sized to receive the threaded shaft 42 of a bolt 16, while blocking the associated bolt head 40 from moving through as suggested in FIGS. 1 and 2.

The exterior panel 50 also includes upper and lower indented temporary-retention portions 64, 66. The upper and lower indented temporary-retention portions 64, 66 are pressed out of alignment from the primary portion 60 into square mount holes 13 of the upright post 22. In this way, the upper and lower indented temporary-retention portions 64, 66 hold the adapter clip 20 in place relative to the rack 12 during installation of the bolts 16 that couple the server slides 14 to the rack 12.

The upper and lower bolt head apertures 61, 63 are arranged through the upper and lower indented temporary-retention portions 64, 66, respectively, as shown in FIG. 4. The mid bolt head aperture 62 is equidistant between the upper and lower bolt head apertures 61, 63.

The interior panel 52 of the adapter clip 20 includes a primary portion 70 that is in a plane parallel to the plane in which the primary portion 60 of the exterior panel 50 resides as shown in FIGS. 2 and 3. The interior panel 52 is formed to include upper, mid, and lower bolt pass-through apertures 71, 72, 73 that are sized to receive the threaded shaft 42 of a bolt 16. The upper, mid, and lower bolt pass-through apertures 71, 72, 73 are aligned with corresponding upper, mid, and lower bolt head apertures 61, 62, 63 of the exterior panel 50.

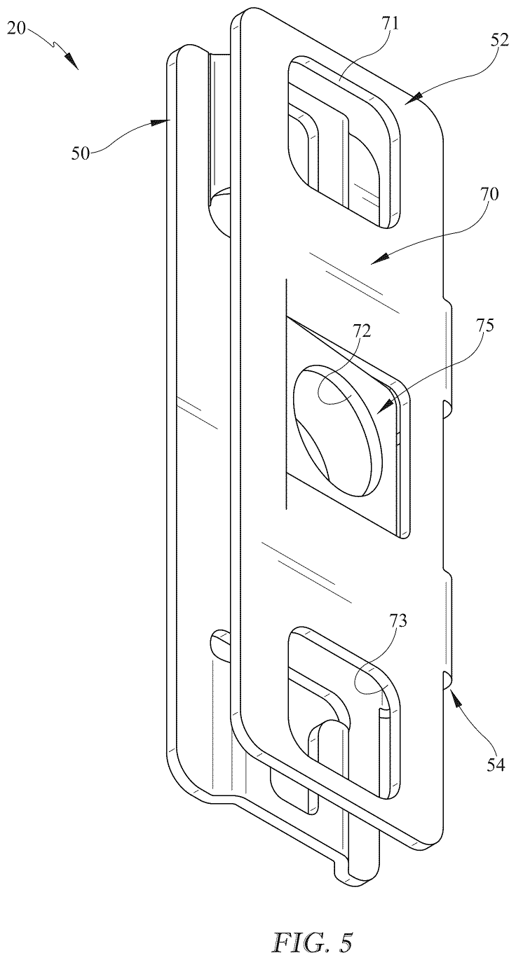

The interior panel 52 also includes an indented temporary-retention portion 75 as shown in FIG. 5. The indented temporary-retention portion 75 is pressed out of alignment from the primary portion 70 into a square mount hole 13 of the upright post 22. In this way, the indented temporary-retention portion 75 holds the adapter clip 20 in place relative to the rack 12 during installation of the bolts 16 that couple the server slides 14 to the rack 12. The mid bolt pass-through head aperture 72 is arranged through the indented temporary-retention portion 75.

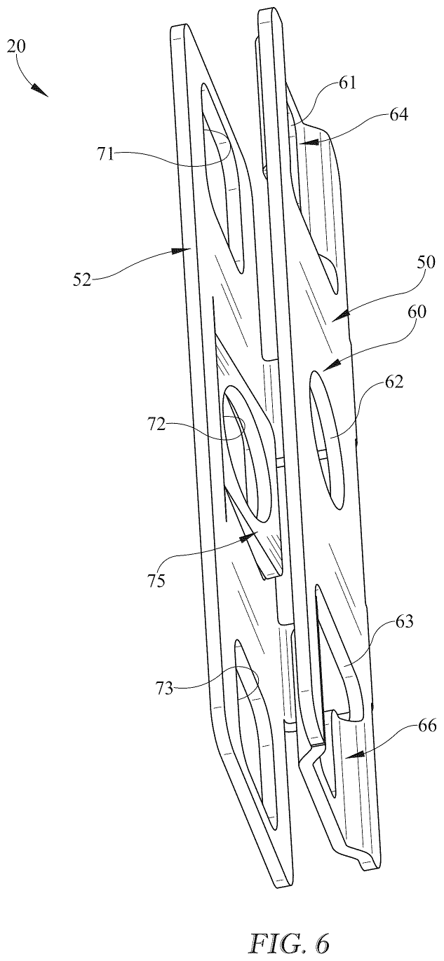

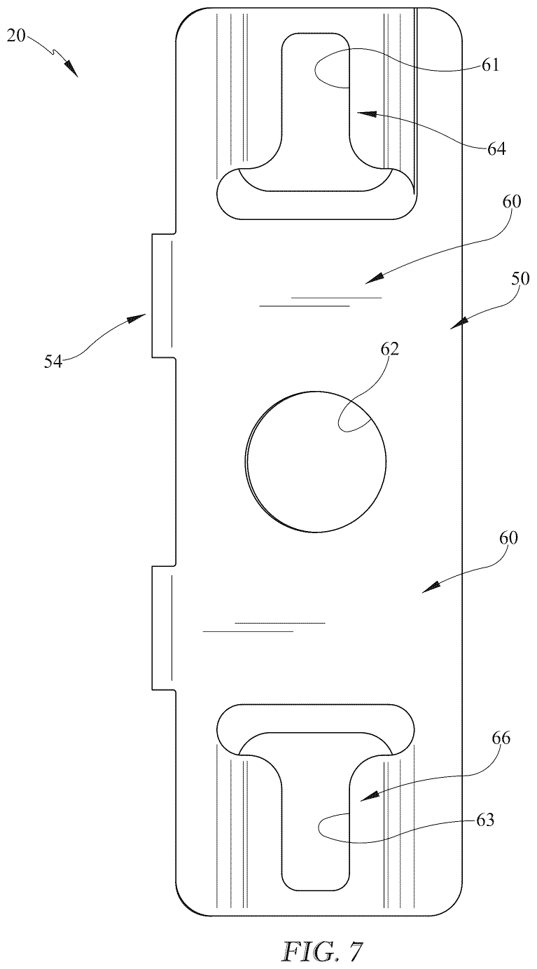

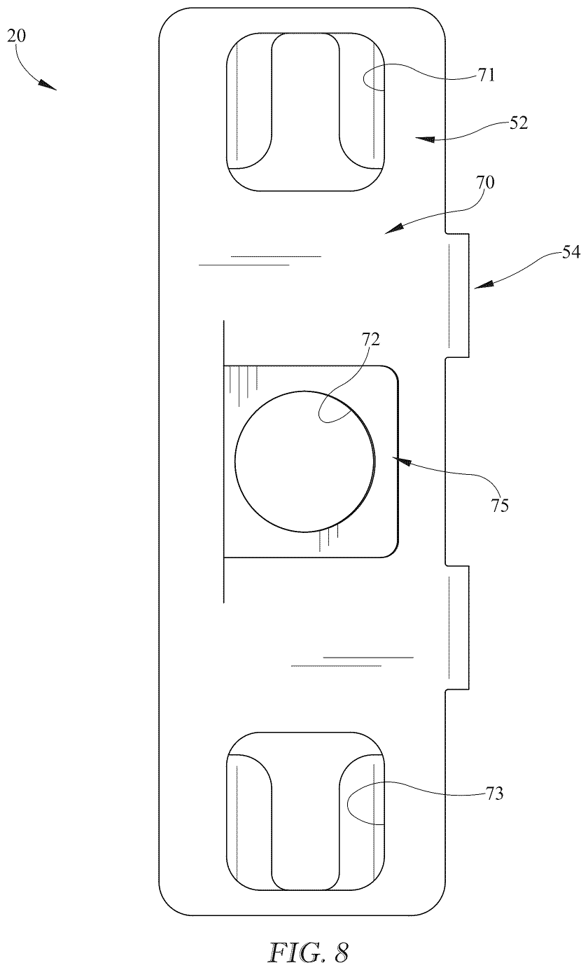

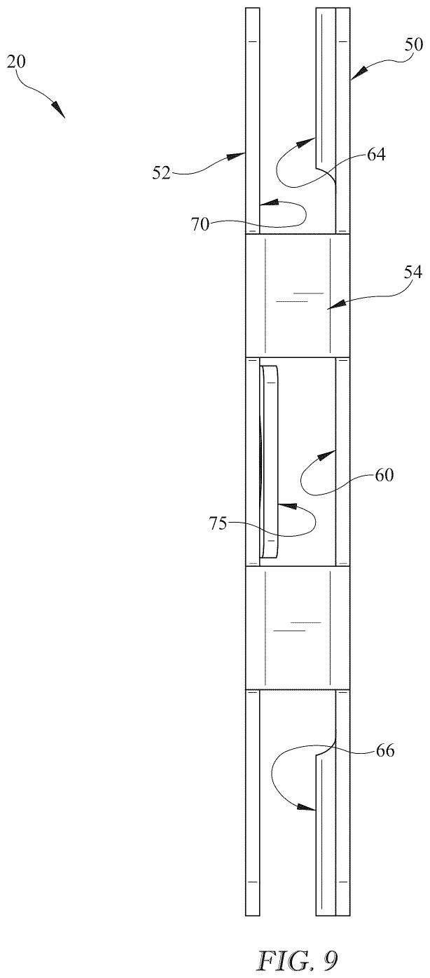

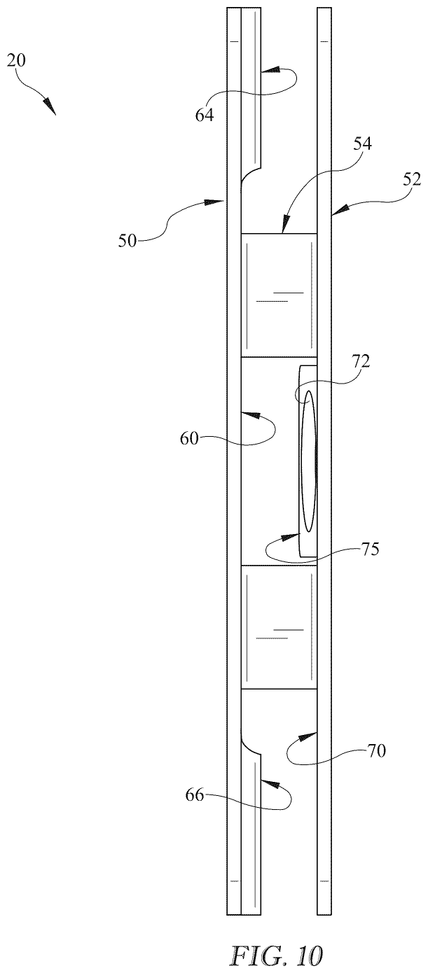

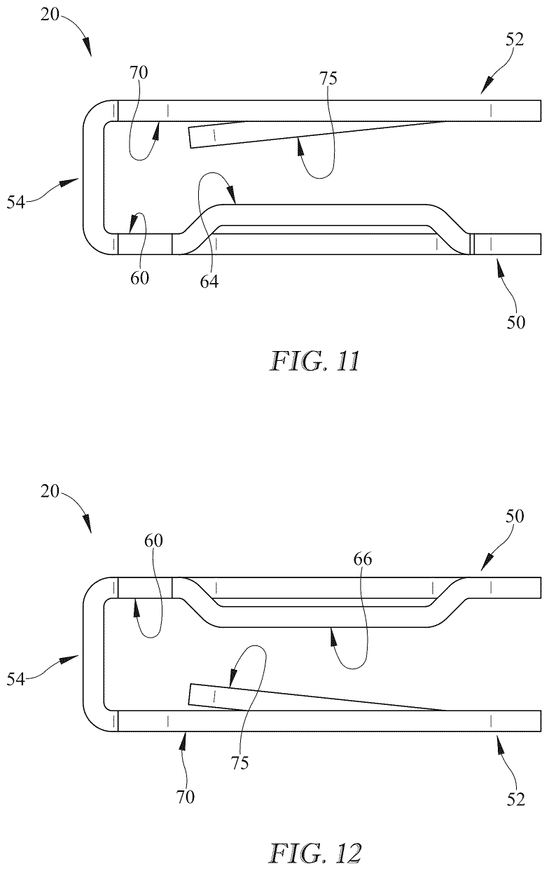

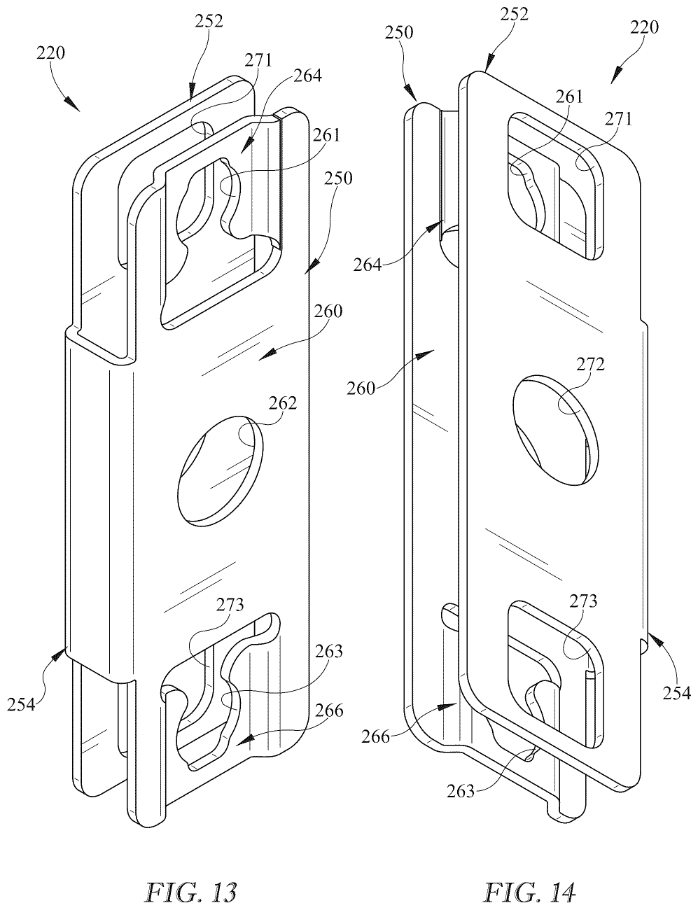

Another embodiment of an adapter clip 220 in accordance with the present disclosure is shown in FIGS. 13 and 14. The adapter clip 220 is substantially similar to the adapter clip 20 shown in FIGS. 1-12 and described herein. Accordingly, similar reference numbers in the 200 series indicate features that are common between the adapter clip 20 and the adapter clip 220. The description of the adapter clip 20 is incorporated by reference to apply to the adapter clip 220, except in instances when it conflicts with the specific description and the drawings of the adapter clip 220.

The adapter clip 220 includes an exterior panel 250, an interior panel 252, and a spine panel 254. The exterior panel 250 is spaced apart from the interior panel 252. The spine panel 254 is illustratively made up of one section shorter than the interior/exterior panels 250, 252.

The exterior panel 250 of the adapter clip 220 includes a primary portion 260 that is in a plane parallel to a plane of the outer face of the upright post 222 as shown in FIGS. 13 and 14. The exterior panel 250 is formed to include upper, mid, and lower bolt head apertures 261, 262, 263.

The exterior panel 250 also includes upper and lower indented temporary-retention portions 264, 266. The upper and lower indented temporary-retention portions 264, 266 are pressed out of alignment from the primary portion 260. In this way, the upper and lower indented temporary-retention portions 264, 266 can hold the adapter clip 220 in place relative to the rack 12.

The upper and lower bolt head apertures 261, 263 are arranged through the upper and lower indented temporary-retention portions 264, 266, respectively, as shown in FIG. 13. Further, the upper and lower bolt head apertures 261, 263 are shaped differently from the corresponding apertures 61, 63 of the adapter clip 20. The mid bolt head aperture 262 is equidistant between the upper and lower bolt head apertures 261, 263.

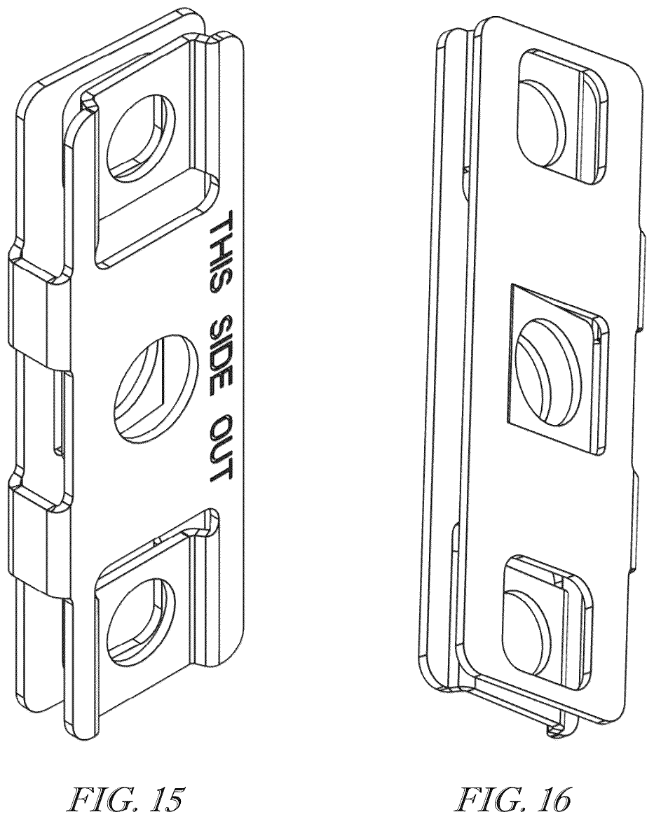

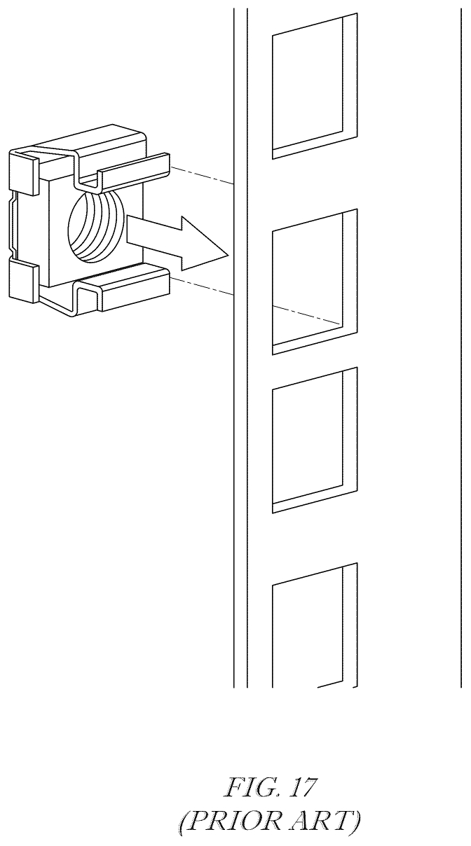

Another embodiment of an adapter clip configured for use in the computer server mount assembly of FIGS. 1-3 is shown in FIGS. 15 and 16. As shown in FIGS. 15 and 16, the upper and lower bolt head apertures arranged through the upper and lower indented temporary-retention portions are shaped differently from the corresponding apertures 61, 63, 261, 263 of the adapter clips 20, 220. The upper and lower bolt head apertures are circular as shown in FIGS. 15 and 16. In other embodiments, the upper and lower bolt head apertures may have another suitable shape.

The interior panel 252 with bolt pass-through apertures 271, 272, 273 as shown in FIG. 14. Unlike the adapter clip 220, the interior panel 252 does not include an indented temporary-retention portion pressed out of alignment with a primary portion of the panel 252. This is because only one or two indented temporary-retention portions are capable of holding the adapter clip 220 in place during assembly of a computer server mount assembly. Moreover, in other embodiments, there may be other or no temporary-retention features integrated into an adapter clip.

Designs in accordance with the present disclosure provide a solution for server and rack mounting applications. The purpose of these adapter clips is to convert square-hole racks to be able to accept slides and meant for round holes. What is special about it is it allows you to mount your slide to the rear of the rack, thus saving valuable clearance for wide chassis.

1. A computer server mount assembly, the assembly comprising
a rack with square mount holes formed in an upright post,
a server slide with round holes formed in attachment flanges, and
adapter clips that provide means for fixing the attachment flanges of the server slides in position relative to the square mount holes of the upright post included in the rack using bolts with heads sized such that they would move through the square mount holes of the upright post without an additional structure.

2. The assembly of claim 1, wherein the adapter clip includes an exterior panel that extends along an outer face of the upright post, an interior panel spaced from the exterior panel that extends along an interior face of the upright post, and a spine panel that extends from the exterior panel to the interior panel along a side face of the upright post.

3. The assembly of claim 2, wherein the exterior panel of the adapter clip includes a primary portion that is parallel to the outer face of the upright post and at least one indented temporary-retention portion that is pressed out of alignment from the primary portion into a square mount hole of the upright post to hold the adapter clip in place relative to the rack during installation of the bolts that couple the server slides to the rack.

4. The assembly of claim 3, wherein the at least one indented temporary-retention portion is formed to include a bolt aperture through which a threaded shaft of an associated bolt passes, and wherein the bolt aperture is sized to block passage of a head of the associated bolt therethrough.

5. The assembly of claim 3, wherein the at least one indented temporary-retention portion includes an upper indented temporary-retention portion and a lower temporary-retention portion.

6. The assembly of claim 2, wherein the interior panel of the adapter clip includes a primary portion that is parallel to the inner face of the upright post and an indented temporary-retention portion that is pressed out of alignment from the primary portion into a square mount hole of the upright post to hold the adapter clip in place relative to the rack during installation of the bolts that couple the server slides to the rack.

7. The assembly of claim 6, wherein the indented temporary-retention portion is formed to include an opening therethrough into which a threaded shaft of a bolt passes.

8. The assembly of claim 1, further comprising threaded nut plates each having threaded holes for retaining the bolts when installed to couple the server slides to the rack.

9. An adapter clip for coupling a server slide with round bolt holes to a rack with square mount holes, the adapter clip comprising
an exterior panel with a plurality of bolt apertures formed therethrough, each of the bolt apertures sized to allow passage of a threaded bolt shaft while blocking passage of a bolt head,
an interior panel spaced from the exterior panel with a plurality of openings formed therethrough and aligned with the bolt apertures of the exterior panel, and
a spine panel that extends from the exterior panel to the interior panel so that the adapter clip generally forms a C-shape when viewed from above.

10. The adapter clip of claim 9, wherein the exterior panel includes a primary portion and at least one indented temporary-retention portion that is pressed out of alignment from the primary portion, the at least one indented temporary-retention portion shaped to engage a square mount hole of the upright post to hold the adapter clip in place relative to the rack.

11. The adapter clip of claim 10, wherein the at least one indented temporary-retention portion is formed to include a bolt aperture.

12. The adapter clip of claim 10, wherein the at least one indented temporary-retention portion includes an upper indented temporary-retention portion and a lower temporary-retention portion.

13. The adapter clip of claim 9, wherein the interior panel of the adapter clip includes a primary portion and an indented temporary-retention portion that is pressed out of alignment from the primary portion, the indented temporary-retention portion shaped to engage a square mount hole of the upright post to hold the adapter clip in place relative to the rack.

14. The adapter clip of claim 13, wherein the indented temporary-retention portion is formed to include a bolt aperture.

15. The adapter clip of claim 9, wherein the spine panel includes two sections spaced that each extend from the exterior panel to the interior panel.
